(19) United States
(12) Patent Application Publication
(10) Pub. No.: US 2025/0163230 A1
(43) Pub. Date: May 22, 2025

(54) FLEXIBLE WINDOW FILM AND DISPLAY APPARATUS COMPRISING THE SAME

(71) Applicant: SAMSUNG SDI CO., LTD., Gyeonggi-do (KR)

(72) Inventor: Yong Woon KIM, Gyeonggi-do (KR)

(73) Assignee: SAMSUNG SDI CO., LTD., Gyeonggi-do (KR)

(21) Appl. No.: 18/947,915

(22) Filed: Nov. 14, 2024

(30) Foreign Application Priority Data
Nov. 16, 2023 (KR) 10-2023-0159230

(51) Int. Cl. C08J 7/046; C08J 7/04; C09D 175/04; G02B 1/14; G02B 1/18; H05K 5/03

(52) U.S. Cl. CPC C08J 7/046; C08J 7/042; C09D 175/04; G02B 1/14; H05K 5/03; C08J 2379/08; C08J 2433/10; C08J 2475/04; G02B 1/18

(57) ABSTRACT

Disclosed herein are a flexible window film, and a display apparatus including the flexible window film. The flexible window film includes a base layer, a hard coating layer on an upper surface of the base layer, a functional coating layer stacked on a lower surface of the base layer, and a buffer layer formed between the base layer and the functional coating layer, wherein the functional coating layer has a modulus of about 50 MPa to about 300 MPa at −20° C.

### CROSS-REFERENCE TO RELATED APPLICATION

The present application claims the benefit of priority of Korean Patent Application No. 10-2023-0159230, filed on Nov. 16, 2023 in the Korean Intellectual Property Office, the entire disclosure of which is incorporated herein by reference.

### FIELD OF THE DISCLOSURE

The present disclosure relates to a flexible window film, and to a display apparatus including the flexible window film.

### DESCRIPTION OF THE RELATED ART

There is a growing interest in flexible display apparatuses. In response to this interest, window films mounted on flexible display apparatuses typically have flexibility. Since such a window film may be configured to protect internal optical devices of a display apparatus, it may be desirable for the window film to have a hard coating layer. For example, the window film includes a base layer and a hard coating layer formed on the base layer.

When included in a flexible display apparatus, the window film is folded in the direction of the base layer or the hard coating layer and unfolded back to an original state thereof hundreds of thousands of times or more. For example, a polyimide film may constitute the base layer. It may be desirable that the window film have good flexural reliability under low temperature conditions and high temperature and high humidity conditions while having good impact resistance.

The technical background of the present disclosure is disclosed in Japanese Patent Laid-open Publication No. 2008-037101 and the like.

### SUMMARY OF THE DISCLOSURE

It is one example aspect of the present disclosure to provide a rainbow mura-free flexible window film.

It is another example aspect of the present disclosure to provide a flexible window film having good flexural reliability under low temperature conditions; and high temperature and high humidity conditions.

In accordance with one example aspect of the present disclosure, a flexible window film includes a base layer, a hard coating layer on, e.g., stacked on, an upper surface of the base layer, a functional coating layer on, e.g., stacked on, a lower surface of the base layer, and a buffer layer formed between the base layer and the functional coating layer, wherein the functional coating layer has a modulus of 50 MPa to 300 MPa at −20° C.

In accordance with another aspect of the present disclosure, an optical display apparatus includes the flexible window film described above.

Example embodiments of the present disclosure provide a rainbow mura-free flexible window film.

Example embodiments of the present disclosure provide a flexible window film having good flexural reliability under low temperature conditions, and under high temperature and high humidity conditions.

### BRIEF DESCRIPTION OF DRAWINGS

FIG. 1 is a cross-sectional view of a window film according to one example embodiment.

### DETAILED DESCRIPTION OF THE DISCLOSURE

Example embodiments of the present disclosure will be described in detail with reference to the accompanying drawing to facilitate practice by one of ordinary skill in the art to which the present disclosure pertains. It should be understood that the present disclosure may be embodied in different ways and is not limited to the following example embodiments.

In the drawing, portions irrelevant to the description will be omitted for clarity. Like components will be denoted by like reference numerals throughout the specification. Lengths, sizes, and the like of components in the drawing are for the purpose of illustrating the disclosure, and the disclosure is not limited thereto.

The terminology used herein is for the purpose of describing example embodiments and is not intended to limit the present disclosure. As used herein, the singular forms, “a,” “an,” and “the” are intended to include the plural forms as well, unless the context clearly indicates otherwise.

Herein, “combination thereof” refers to a mixture, stack, composite, copolymer, alloy, blend, reaction product, or the like of stated components.

In addition, it will be understood that the terms “includes,” “comprises,” “including” and/or “comprising,” when used in this specification, specify the presence of stated features, numbers, steps, components, or combinations thereof, but do not preclude the presence or addition of one or more other features, numbers, steps, components, or combinations thereof.

Herein, spatially relative terms such as “upper” and “lower” are defined with reference to the accompanying drawings. Thus, it will be understood that the term “upper surface” can be used interchangeably with the term “lower surface,” and when an element such as a layer or film is referred to as being placed “on” another element, the element can be directly placed on the other element, or intervening element(s) may be present. On the other hand, when an element is referred to as being placed “directly on” another element, there are no intervening element(s) therebetween.

Herein, the term “(meth)acryl” refers to acryl and/or methacryl.

As used herein to represent a specific numerical range, the expression “X to Y” means “greater than or equal to X and less than or equal to Y (X≤ and ≤Y).”

When the term “about” is used in this specification in connection with a numerical value, it is intended that the associated numerical value include a tolerance of 10% around the stated numerical value. When ranges are specified, the range includes all values therebetween such as increments of 0.1%.

In accordance with one aspect of the present disclosure, a flexible window film includes a base layer, a hard coating layer on, e.g., stacked on, an upper surface of the base layer, a functional coating layer on, e.g., stacked on, a lower surface of the base layer, and a buffer layer formed between the base layer and the functional coating layer, wherein the functional coating layer has a modulus of 50 MPa to 300 MPa at −20° C. Through a combination of adjusting the modulus of the functional coating layer to the range described above and forming the buffer layer between the base layer and the functional coating layer, the flexible window film can have improved flexural reliability under low temperature conditions, and under high temperature and high humidity conditions.

Herein, “modulus” of the base layer refers to a storage modulus (E′) of the base layer measured using a dynamic mechanical analyzer (DMA) (Q800 model, TA instruments Inc.). For example, the storage modulus is obtained using dynamic mechanical analysis in tensile mode under conditions of a frequency of 1 Hz and a heating rate of 3° C./min from −40° C. to 70° C. after clamping both ends of a sample with a space of about 7 mm therebetween.

Herein, “modulus” of the functional coating layer refers to a storage modulus (E′) of the functional coating layer measured using a dynamic mechanical analyzer (Q800 model, TA instruments Inc.). For example, the storage modulus is obtained using dynamic mechanical analysis in tensile mode under conditions of a frequency of 1 Hz and a heating rate of 3° C./min from −40° C. to 70° C. after clamping both ends of a sample with a space of about 7 mm therebetween.

The base layer supports the window film to enhance mechanical strength of the window film.

The base layer may be formed of or include an optically transparent flexible resin. According to one example embodiment, the resin may include at least one of a polyamideimide resin or a polyimide resin. Each, or at least one, of the polyamideimide resin and the polyimide resin may be prepared by a typical method known in the art. The polyamideimide resin may include a block copolymer of poly(amideimide), without being limited thereto. For example, the base layer is or includes a polyimide (PI) resin film.

According to one example embodiment, the base layer may be or include a soluble polyimide resin film. The soluble polyimide resin film is partially dissolved in a solvent, or the like, to facilitate formation of the buffer layer described below at the boundary of the resin film. According to one example embodiment, the solvent may include at least one of methyl ethyl ketone, methyl isobutyl ketone, propylene glycol monomethyl ether, N,N-dimethylacetamide, or methyl pyrrolidone.

The soluble polyimide resin film may be prepared by a typical method known in the art.

The base layer may have a modulus of about 3 GPa to about 10 GPa, for example, 3, 4, 5, 6, 7, 8, 9, 10 GPa, 6 GPa to 10 GPa, for example 6 GPa to 8 GPa, at 25° C. Within these ranges, the base layer can reduce or prevent cracking of the window film upon folding the window film in a direction of the base layer and/or in a direction of the hardcoating layer and unfolding the window film to an original state thereof, while ensuring good flexural reliability of the window film.

The modulus of the base layer may be adjusted to the range described above by adjusting the weight average molecular weight of a resin in a resin film forming the base layer, without being limited thereto.

According to one example embodiment, the base layer may have a modulus gradient with respect to the functional coating layer to facilitate improvement in flexural reliability and impact resistance of the window film under low temperature conditions and under high temperature and high humidity conditions. For example, a ratio of the modulus of the functional coating layer at about 25° C. to the modulus of the base layer at 25° C. (the modulus of the functional coating layer at 25° C.: the modulus of the base layer at 25° C.) may range from about 1:50 to about 1:2,000, for example, 1:50 to 1:1,000. Here, the modulus of each of the base layer and the functional coating layer is a value in MPa.

The base layer may have a thickness of about 10 μm to about 200 μm, for example 10, 20, 30, 40, 50, 60, 70, 80, 90, 100, 110, 120, 130, 140, 150 μm, 20 μm to 150 μm or 30 μm to 100 μm. Within these ranges, the base layer can be included in the window film.

The base layer may be or include a monolayer film. However, the present disclosure is not limited thereto, and the base layer may be or include a stack of two or more identical or different resin films attached to each other by, e.g., an adhesive layer, a bonding layer, or an adhesive bonding layer.

The base layer may further include a primer layer or a coating layer providing additional functionality on one or both surfaces thereof. According to one example embodiment, the base layer may be or include a monolayer film formed of or including any of the resins described above without a primer layer or an adhesion-enhancing layer on one or both surfaces thereof.

The buffer layer is formed on the lower surface of the base layer. According to one example embodiment, the buffer layer may be directly formed on the base layer. Herein, the expression “directly formed” indicates the fact that no adhesive layer or bonding layer is interposed between the base layer and the buffer layer.

According to one example embodiment, the buffer layer is an intermixing layer of the base layer and the functional coating layer. Herein, by “intermixing layer,” it is meant that the buffer layer is a layer in which a main component of the base layer is mixed with a main component of the functional coating layer. The buffer layer can facilitate the reduction or elimination of rainbow mura. For example, forming the buffer layer between the base layer and the functional coating layer may be effective at the reduction or elimination of rainbow mura, as compared to forming the buffer layer between the base layer and the hard coating layer.

The buffer layer is formed to a predetermined or desired thickness at an interface between the base layer and the functional coating layer. The buffer layer can mitigate a difference in refractive index between the base layer and the functional coating layer in a thickness direction of the window film. Accordingly, when included in a display apparatus, the window film can ensure good screen quality through the reduction or elimination of rainbow mura. The difference in refractive index between the base layer and the functional coating layer may be in the range of about 0 to about 0.7, for example 0, 0.1, 0.2, 0.3, 0.4, 0.5, 0.6, 0.7, 0.1 to 0.4 (the base layer has a higher refractive index than the functional coating layer). Within these ranges, the buffer layer can be highly effective at the reduction or elimination of rainbow mura.

In conjunction with the functional coating layer having a modulus in the range described below at −20° C., the buffer layer can contribute to improving flexural reliability of the flexible window film under low temperature conditions and under high temperature and high humidity conditions.

According to one example embodiment, in the buffer layer, the content of the main component of the base layer, for example, a polyimide resin, may be gradually decreased from an interface between the buffer layer and the base layer to an interface between the buffer layer and the functional coating layer.

According to one example embodiment, in the buffer layer, the content of a main component of the functional coating layer, for example, at least one of a urethane resin or a urethane (meth)acrylic resin, may be gradually decreased from the interface between the buffer layer and the functional coating layer to the interface between the buffer layer and the base layer.

In one example embodiment, the buffer layer may refer to a layer in which the main component of the base layer, for example, a polyimide resin, is mixed with the main component of the functional coating layer, for example, at least one of a urethane resin or a urethane (meth)acrylic resin.

According to one example embodiment, the buffer layer may be formed by partial dissolution of the base layer by a solvent contained in a functional coating layer composition described below upon application of the functional coating layer composition to the lower surface of the base layer.

The presence of the buffer layer in the flexible window film may be determined by examining a cross-section of the window film using a scanning electron microscope (SEM), or by scanning a cross-section of the window film in the thickness direction thereof by surface infrared spectroscopy.

The buffer layer may have a thickness of about 0.1 μm to about 5 μm, for example, 0.1, 0.2, 0.3, 0.4, 0.5, 0.6, 0.7, 0.8, 0.9, 1, 2, 3 μm, 0.3 μm to 3 μm. Within these ranges, the buffer layer can be included in the flexible window film.

The functional coating layer is formed on the lower surface of the buffer layer. According to one example embodiment, the functional coating layer is directly formed on the buffer layer. Herein, the expression “directly formed” indicates that no adhesive layer or bonding layer is interposed between the functional coating layer and the buffer layer.

The functional coating layer has a modulus of about 50 MPa to about 300 MPa at −20° C. When the modulus of the functional coating layer at −20° C. is less than about 50 MPa, the flexible window film can have poor flexural reliability under high temperature and high humidity conditions. When the modulus of the functional coating layer at −20° C. exceeds about 300 MPa, the flexible window film can have poor flexural reliability under low temperature conditions. In one example embodiment, the functional coating layer may have a modulus of 50, 60, 70, 80, 90, 100, 110, 120, 130, 140, 150, 160, 170, 180, 190, 200, 210, 220, 230, 240, 250, 260, 270, 280, 290, 300 MPa, 50 MPa to 200 MPa at −20° C.

According to one example embodiment, the functional coating layer may have a modulus of about 5 MPa to about 200 MPa at 25° C., for example, 5 MPa to 150 MPa, for example 10 MPa to 100 MPa. Within these ranges, the functional coating layer can facilitate the achievement of the desired effects of the flexible window film according to the present disclosure.

According to one example embodiment, the functional coating layer may have a modulus of about 1 MPa to about 150 MPa at 60° C., for example 1, 5, 10, 15, 20, 25, 30, 35, 40, 45, 50, 55, 60, 65, 70, 75, 80, 85, 90, 95, 100, 105, 110,115, 120, 125, 130, 135, 140,145, 150 MPa, 1 MPa to 100 MPa, or for example 1 MPa to 50 MPa. Within these ranges, the functional coating layer can facilitate the achievement of the desired effects of the flexible window film according to the present disclosure.

According to one example embodiment, a ratio of the modulus of the functional coating layer at 60° C. to the modulus of the functional coating layer at −20° C. (the modulus of the functional coating layer at 60° C.: the modulus of the functional coating layer at −20° C.) may range from about 1:2 to about 1:10, 1:2, 1:3, 1:4, 1:5, 1:6, 1:7, 1:8, 1:9, 1:10, for example, 1:4 to 1:8. Within these ranges, the flexible window film can provide stable flexural reliability in a broad range of low temperatures and in a broad range of high temperatures and high humidity.

While not particularly restricted, the functional coating layer may be or include an impact resistant coating layer. When the impact resistant coating layer is the functional coating layer, the flexible window film can be disposed at an outermost side of an optical display device.

According to one example embodiment, the functional coating layer may include a cured product of a functional coating layer composition including an elastomer resin. For example, the elastomer resin may include at least one of a urethane resin or a urethane (meth)acrylic resin. Each, or at least one, of the urethane resin and the urethane (meth)acrylic resin may be prepared by a method known in the art, or may be or include a commercially available product. For example, the elastomer resin is or includes a urethane (meth)acrylic resin. Use of the urethane (meth)acrylic resin as the elastomer resin can facilitate the achievement of the desired effects described herein. For example, the urethane (meth)acrylic resin may be or include a urethane (meth)acrylate resin.

In one example embodiment, the urethane resin is a urethane (meth)acrylic resin and may have a weight average molecular weight of about 100 g/mol to about 500 g/mol, for example, 100, 150, 200, 250, 300, 350, 400, 450, 500 g/mol, 150 g/mol to 400 g/mol, before curing. Herein, the weight average molecular weight may be obtained based on polystyrene conversion by gel permeation chromatography.

In one example embodiment, the urethane (meth)acrylic resin may be prepared by reacting a bi- or higher functional polyol with a bi- or higher functional isocyanate to prepare a urethane prepolymer, followed by reacting the prepared urethane prepolymer with a (meth)acrylate containing an alkyl group having a hydroxyl group. The polyol may include at least one of an aromatic polyol, an aliphatic polyol, or a cycloaliphatic polyol. For example, the polyol is a polyurethane compound formed of or including at least one of an aliphatic polyol or a cycloaliphatic polyol. The polyol may include at least one of polyester diol, polycarbonate diol, polyolefin diol, polyether diol, polythioether diol, polysiloxane diol, polyacetal diol, or polyesteramide diol, without being limited thereto. The polyfunctional isocyanate may include at least one of any aliphatic, cycloaliphatic, or aromatic isocyanate. The (meth)acrylate containing an alkyl group having a hydroxyl group is a (meth)acrylate containing a C1 to C10 alkyl group having at least one hydroxyl group at an ester site thereof, and may include 2-hydroxyethyl (meth)acrylate and the like.

In preparation of the urethane prepolymer, a chain extender may be further used. The chain extender may include at least one of a diol, such as an aliphatic diol, an amino alcohol, a diamine, a hydrazine, a hydrazide, or a mixture thereof. In addition, in preparation of the urethane prepolymer, a tin compound, for example, at least one of a tin salt of carboxylic acid, or an amine, for example, dimethylcyclohexylamine or triethylenediamine, may be further included as a catalyst to promote formation of a urethane bond. Moreover, in preparation of the urethane prepolymer, other typical additives, such as at least one of a surfactant, a flame retardant, fillers, and a pigment, may be further used.

The urethane resin is a urethane (meth)acrylic resin and may be or include an elastomer product manufactured by DuPont.

The modulus of the functional coating layer at −20° C., 25° C., and 60° C. may be adjusted to the ranges described above by adjusting the weight average molecular weight of the elastomer resin, the content of the elastomer resin in the functional coating layer composition, the curing rate of the functional coating layer composition (for example, the photocuring rate or thermal curing rate of the composition), the content of a photoinitiator in the functional coating layer composition, and the like.

In one example embodiment, the photoinitiator may be or include a radical photoinitiator. The photoinitiator may be or include any suitable photoinitiator that can cure the elastomer resin in a curing process through light irradiation or the like, without limitation. For example, the photoinitiator may be or include at least one of a benzoin photoinitiator, an acetophenone photoinitiator, a hydroxy ketone photoinitiator, an aminoketone photoinitiator, or a phosphine oxide photoinitiator. For example, the photoinitiator may include at least one of benzoin, benzoin methyl ether, benzoin ethyl ether, benzoin isopropyl ether, benzoin n-butyl ether, benzoin isobutyl ether, acetophenone, dimethylamino acetophenone, 2,2-dimethoxy-2-phenylacetophenone, 2,2-diethoxy-2-phenylacetophenone, 2-hydroxy-2-methyl-1-phenylpropan-1-one, 1-hydroxycyclohexylphenylketone, 2-methyl-1-[4-(methylthio)phenyl]-2-morpholino-propan-1-one, 4-(2-hydroxyethoxy)phenyl-2-(hydroxy-2-propyl)ketone, benzophenone, p-phenylbenzophenone, 4,4-diethylaminobenzophenone, dichlorobenzophenone, 2-methylanthraquinone, 2-ethylanthraquinone, 2-t-butylanthraquinone, 2-aminoanthraquinone, 2-methylthioxanthone, 2-ethylthioxanthone, 2-chlorothioxanthone, 2,4-dimethylthioxanthone, 2,4-diethylthioxanthone, benzyl dimethyl ketal, acetophenone dimethyl ketal, p-dimethylamino benzoic acid ester, oligo[2-hydroxy-2-methyl-1-[4-(1-methylvinyl)phenyl]propanone], 2,4,6-trimethylbenzoyl-diphenyl-phosphine oxide, 1-hydroxy-cyclohexyl-phenyl ketone, and the like. For example, the photoinitiator is or includes a hydroxy ketone photoinitiator.

According to one example embodiment, the functional coating layer may be formed of or include a functional coating layer composition including about 100 parts by weight of a base resin including at least one of a urethane resin or a urethane (meth)acrylic resin; and about 0.5 parts by weight to about 1.5 parts by weight, for example, 0.5, 0.6, 0.7, 0.8, 0.9, 1.0, 1.1, 1.2, 1.3, 1.4, 1.5 parts by weight, 0.5 parts by weight to 1 part by weight, of a photoinitiator in terms of solid content, wherein the functional coating layer composition further includes a solvent. The solvent will be described in detail further below. Within this range of content of the photoinitiator, the functional coating layer can readily satisfy the modulus parameters described above.

The functional coating layer composition may further include typical additives such as or including at least one of a UV absorber, a leveling agent, a heat stabilizer, and the like.

According to one example embodiment, the functional coating layer composition includes a solvent configured to dissolve the base layer to form the buffer layer. The solvent is configured to dissolve a portion of the base layer to form the buffer layer between the base layer and the functional coating layer. The solvent may be appropriately selected depending on the type of main component of the base layer. According to one example embodiment, when the base layer is a polyimide resin, the solvent may include at least one of methyl isobutyl ketone, propylene glycol monomethyl ether, N,N-dimethylacetamide, or methyl pyrrolidone.

The hard coating layer is formed on the base layer. According to one example embodiment, the hard coating layer is directly formed on the base layer. Herein, the expression “directly formed” indicates that no adhesive layer, bonding layer, or adhesive bonding layer is interposed between the hard coating layer and the base layer. As will be described below, the hard coating layer may be formed by coating a hard coating layer composition directly onto one surface of the base layer, followed by curing.

In one example embodiment, the buffer layer as described above is not formed between the hard coating layer and the base layer.

The hard coating layer may have a thickness of about 1 μm to about 50 μm, for example 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50 μm, 3 μm to 30 μm, more for example 4 μm to 20 μm. Within these ranges, the hard coating layer can be included in the flexible window film.

The hard coating layer may be formed of or include a hard coating layer composition including at least one (meth)acrylic resin. The hard coating layer composition may further include at least one of a crosslinking agent or an initiator. For example, the hard coating layer composition consists of, or includes, the (meth)acrylic resin and the initiator without the crosslinking agent.

In one example embodiment, the hard coating layer may consist of, or include, the (meth)acrylic resin and the initiator without the crosslinking agent.

The (meth)acrylic resin may include a (meth)acrylic resin obtained by polymerization of a (meth)acrylic monomer alone or by polymerization of the (meth)acrylic monomer with a comonomer copolymerizable with the (meth)acrylic monomer. The (meth)acrylic monomer may include a typical monomer known in the art. The comonomer may include a typical monomer known in the art that is copolymerizable with the (meth)acrylic monomer.

In one example embodiment, the (meth)acrylic resin may include a resin having a (meth)acrylate group at an end thereof. For example, the (meth)acrylic resin may include a dendritic aliphatic compound having a (meth)acrylate group at an end thereof. With the dendritic structure, the aliphatic compound may have many (meth)acrylate groups at a molecular end thereof and thus can have high reactivity.

The (meth)acrylic resin may include one or more (meth)acrylic resins. These (meth)acrylic resins may be included alone or in combination thereof. In particular, the (meth)acrylic resin may include at least one of a dendrimer type (meth)acrylic resin or a hyper-branched (meth)acrylic resin. Herein, the dendrimer type (meth)acrylic resin refers to a (meth)acrylic resin branched with high regularity, and the hyper-branched (meth)acrylic resin refers to a (meth)acrylic resin branched with relatively low regularity compared to the dendrimer type (meth)acrylic resin. The hyper-branched (meth)acrylic resin may be highly soluble in a solvent due to low viscosity thereof compared to a linear (meth)acrylic resin.

The dendrimer type (meth)acrylic resin may be or include a multibranched (dendrimer type) polyester (meth)acrylate having a (meth)acrylate group at an end thereof, without being limited thereto. The hyper-branched (meth)acrylic resin may be or include a multibranched (dendritic) poly(meth)acrylate having a (meth)acrylate group at an end thereof, without being limited thereto. In one example embodiment, the hyper-branched (meth)acrylic resin may be or include a multibranched (dipentaerythritol hexaacrylate-linked) poly(meth)acrylate having dipentaerythritol as a core and a (meth)acrylate group at an end thereof, without being limited thereto.

The (meth)acrylate resin may have a weight average molecular weight of about 5,000 g/mol to about 30,000 g/mol, for example, 10,000 g/mol to 25,000 g/mol. Within these ranges, the window film can have good hardness and scratch resistance.

The initiator is or includes a radical photoinitiator and may include a typical photoinitiator known in the art. For example, the initiator may include at least one of a hydroxy ketone photoinitiator, a phosphine oxide photoinitiator, a benzoin photoinitiator, or an aminoketone photoinitiator. The initiator may be present in an amount of about 1 part by weight to about 10 parts by weight, for example 1 part by weight to 5 parts by weight, relative to 100 parts by weight of the (meth)acrylic resin. Within these ranges, the initiator can ensure adequate curing of the hard coating layer composition without deterioration in optical or physical properties of the window film.

In another example embodiment, the hard coating layer may include the (meth)acrylic resin, the crosslinking agent, and the initiator.

The crosslinking agent forms a crosslinked structure through reaction with the (meth)acrylic resin, and may include a (meth)acrylate compound having at least one (meth)acrylate group, for example at least two (meth)acrylate groups, and for example 2 to 20 (meth)acrylate groups.

In one example embodiment, the crosslinking agent may include a polyfunctional (meth)acrylate. The polyfunctional (meth)acrylate can further improve hardness and flexibility of the hard coating layer.

The crosslinking agent may be present in an amount of about 5 parts by weight to about 150 parts by weight, for example 5 parts by weight to 100 parts by weight, relative to 100 parts by weight of the (meth)acrylic resin. Within these ranges, the crosslinking agent can improve hardness and flexural reliability of the hard coating layer.

The hard coating layer composition may further comprise an additive. The additive can provide additional functionality to the window film. The additive may include any additive commonly added to window films. For example, the additive may include at least one of a leveling agent, a UV absorber, a reaction inhibitor, an adhesion enhancer, a thixotropy-imparting agent, a conductivity-imparting agent, a color-adjusting agent, a stabilizer, an antistatic agent, and an antioxidant. The additive may be present in an amount of about 0.01 parts by weight to about 5 parts by weight, for example 0.1 parts by weight to 3 parts by weight, relative to 100 parts by weight of the (meth)acrylic resin. Within these ranges, the additive can provide the intended effects while ensuring good hardness and flexibility of the window film.

The hard coating layer composition may further include a solvent to secure coatability, workability, or processability. The solvent may include at least one of methyl ethyl ketone, methyl isobutyl ketone, propylene glycol monomethyl ether, or N,N-dimethylacetamide, without being limited thereto. The solvent may be present in the balance amount in the hard coating layer composition.

The hard coating layer may be formed by coating the hard coating layer composition onto one surface of the base layer, followed by curing. A method of coating the hard coating layer composition onto the base layer is not particularly restricted. For example, coating of the hard coating layer onto the base layer may be conducted by bar coating, spin coating, dip coating, roll coating, flow coating, die coating, or the like. Curing of the hard coating layer composition may include at least one of photocuring or thermal curing. Photocuring may include irradiating the hard coating layer composition with light having a wavelength of about 400 nm or less at a fluence of about 10 mJ/cm² to about 1,000 mJ/cm². Thermal curing may include applying the hard coating layer composition to a predetermined or desired thickness to the base layer, followed by drying in a range of about 80° C. to about 150° C. for about 5 to about 30 minutes.

The window film may further include an anti-fingerprint layer formed on an upper surface of the hard coating layer. When the window film is disposed at an outermost side of a display apparatus, the anti-fingerprint layer can hinder or prevent a screen of the display apparatus from being stained by fingers touching the screen. The anti-fingerprint layer may be or include a fluorine anti-fingerprint layer, without being limited thereto. The anti-fingerprint layer may have a thickness of about 0.1 μm to about 1 μm.

The window film may be optically clear to be included in a transparent display apparatus. The window film may have a light transmittance of about 80% or greater, for example 85% to 100%, and a haze of about 1% or less, for example 0% to 1%, as measured in the visible spectrum, for example at a wavelength of about 400 nm to about 800 nm. Within this range, the window film can be included as a window film for display apparatuses.

In evaluating the flexibility of the window film upon repetition of a cycle in which the window film is bent to a curvature radius of 1 mm under high temperature and high humidity conditions (for example, at 60° C. and 95% relative humidity (RH)) and/or under low temperature conditions (for example, at −40° C.), a minimum number of cycles at which cracking occurs on the hard coating layer or the base layer may be about 100,000 or more. Thus, the window film can be included in a flexible display apparatus due to good flexural reliability thereof under high temperature and high humidity conditions and/or low temperature conditions.

The window film may have a thickness of about 30 μm to about 200 μm, for example, 30 μm to 80 μm. Within these ranges, the window film can be a flexible window film for display apparatuses.

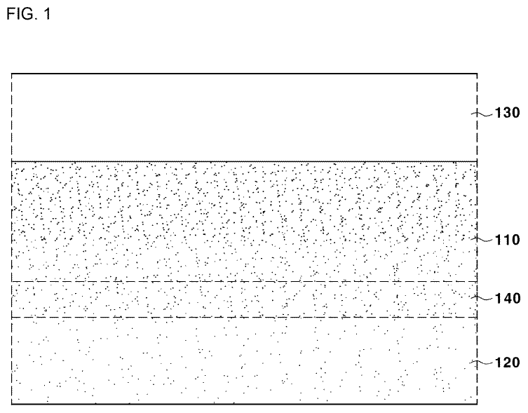

In the following, a window film according to one example embodiment of the present disclosure will be described with reference to FIG. 1.

Referring to FIG. 1, the window film includes a base layer 110, a hard coating layer 130 formed on one surface of the base layer 110, a functional coating layer 120 formed on the other surface of the base layer 110, and a buffer layer 140 formed at an interface between the base layer 110 and the functional coating layer 120.

In FIG. 1, each of the interface between the base layer 110 and the buffer layer 140 and the interface between the buffer layer 140 and the functional coating layer 120 is indicated by a dotted line. This indicates that the base layer 110 and the buffer layer 140 are not divided from each other by a plane and the buffer layer 140 and the functional coating layer 120 are not divided from each other by a plane.

In the following, a method of manufacturing the window film will be described.

The window film may be manufactured by coating the hard coating layer composition onto an upper surface of the base layer, followed by curing, to form the hard coating layer on the base layer, and coating the functional coating layer composition onto a lower surface of the base layer, followed by curing, to form the buffer layer and the functional coating layer at the same time.

Coating of each composition may be conducted by a typical method known in the art. For example, coating of each composition may be conducted by spray coating, die coating, or spin coating, without being limited thereto. Curing may include at least one of photocuring or thermal curing. Conditions of photocuring or thermal curing may be adjusted according to the thickness of each layer, the type of material forming each layer, and the like. In one example embodiment, curing of each composition may be conducted in combination with drying or the like to reduce surface roughness of each layer or to shorten the time required to complete curing.

In the following, a display apparatus according to the present disclosure will be described.

The display apparatus according to the present disclosure includes the flexible window film according to the present disclosure as described above. The display apparatus may be or include a flexible display apparatus, or may be or include a non-flexible display apparatus. For example, the display apparatus may be or include a light emitting diode display including an organic light emitting diode display apparatus and the like, a liquid crystal display, or the like, without being limited thereto.

Next, the present disclosure will be described in more detail with reference to some examples. It should be understood that these examples are provided for illustration only and are not to be construed in any way as limiting the present disclosure.

### Preparative Example: Preparation of Hard Coating Layer Composition

A hard coating layer composition was prepared by mixing 67 parts by weight of a dendrimer type acrylic resin (Sirius 501, Osaka Organic Chemical Industry Ltd.) with 1 part by weight of a photoinitiator (Irgacure-184, BASF Co., Ltd.), 31.5 parts by weight of methyl ethyl ketone, and 0.5 parts by weight of a leveling agent (BYK-350).

### Example 1

An impact resistant layer composition including 100 parts by weight of a polyurethane resin (Elastomer E24, DuPont Inc.), 0.5 parts by weight of a photoinitiator (1-hydroxy-cyclohexyl-phenyl ketone, Irgacure-184, BASF Co., Ltd.), and 15 parts of N,N-dimethylacetamide as a solvent, was prepared.

A polyimide film (thickness: 50 μm, modulus: 6.5 GPa, Kolon Industries Inc.) was used as a base layer. The modulus of the base layer was measured by the method described above.

The hard coating layer composition prepared in Preparative Example was coated onto an upper surface of the base layer, followed by drying at 100° C. for 10 minutes, thereby forming a hard coating layer having a thickness of 5 μm. The prepared impact resistant layer composition was coated to a predetermined or desired thickness onto a lower surface of the base layer, followed by drying at 80° C. for 30 minutes, and then the composition was irradiated with UV light at a fluence of 900 mJ/cm² to form a buffer layer and an impact resistant layer having a thickness of 40 μm, thereby manufacturing a window film. The buffer layer composed of a mixture of the polyimide resin and the polyurethane resin was formed between the base layer and the impact resistant layer. The base layer, the buffer layer, and the impact resistant layer were integrally formed with one another.

### Example 2

A window film was manufactured in the same manner as in Example 1, with a difference that the thickness of the impact resistant layer was changed to 20 μm. The window film had a buffer layer composed of a mixture of the polyimide resin and the polyurethane resin between the base layer and the impact resistant layer. The base layer, the buffer layer, and the impact resistant layer were integrally formed with one another.

### Example 3

An impact resistant layer composition including 100 parts by weight of a polyurethane resin (Elastomer E24, DuPont Inc.) and 1 part by weight of a photoinitiator (Irgacure-184, BASF Co., Ltd.) was prepared. A window film was manufactured in the same manner as in Example 1, with a difference that the prepared impact resistant layer composition was used. The window film had a buffer layer composed of a mixture of the polyimide resin and the polyurethane resin between the base layer and the impact resistant layer. The base layer, the buffer layer, and the impact resistant layer were integrally formed with one another.

### Comparative Example 1

An impact resistant layer composition including 100 parts by weight of a polyurethane resin (Elastomer E24, DuPont Inc.) and 2 parts by weight of a photoinitiator (Irgacure-184, BASF Co., Ltd.) was prepared. A window film was manufactured in the same manner as in Example 1, with a difference that the prepared impact resistant layer composition was used. The window film had a buffer layer composed of a mixture of the polyimide resin and the polyurethane resin between the base layer and the impact resistant layer. The base layer, the buffer layer, and the impact resistant layer were integrally formed with one another.

### Comparative Example 2

An impact resistant layer composition including 100 parts by weight of a polyurethane resin (Elastomer E24, DuPont Inc.) and 0.2 parts by weight of a photoinitiator (Irgacure-184, BASF Co., Ltd.) was prepared. A window film was manufactured in the same manner as in Example 1, with a difference that the prepared impact resistant layer composition was used. The window film had a buffer layer composed of a mixture of a polyimide resin and the polyurethane resin between the base layer and the impact resistant layer.

### Comparative Example 3

An impact resistant layer composition including 100 parts by weight of a polyurethane resin (Elastomer E24, DuPont Inc.) and 0.5 parts by weight of a photoinitiator (Irgacure-184, BASF Co., Ltd.) was prepared. The impact resistant layer composition was free from dimethylacetamide as a solvent. A window film was manufactured in the same manner as in Example 1, with a difference that the prepared impact resistant layer composition was used.

The window film did not have a buffer layer composed of a mixture of the polyimide resin and the polyurethane resin between the base layer and the impact resistant layer.

### Comparative Example 4

An impact resistant layer composition including 100 parts by weight of a polyurethane resin (Elastomer E24, DuPont Inc.) and 0.5 parts by weight of a photoinitiator (Irgacure-184, BASF Co., Ltd.) was prepared. The impact resistant layer composition was free from dimethylacetamide as a solvent.

A hard coating layer composition was prepared by mixing 67 parts by weight of a dendrimer type acrylic resin (Sirius 501, Osaka Organic Chemical Industry Ltd.) with 1 part by weight of a photoinitiator (Irgacure-184, BASF Co., Ltd.), 31.5 parts by weight of N,N-dimethylacetamide, and 0.5 parts by weight of a leveling agent (BYK-350).

A window film was manufactured in the same manner as in Example 1, with a difference that the prepared impact resistant layer composition and the prepared hard coating layer composition were used. The window film had a buffer layer between the base layer and the hard coating layer, rather than between the base layer and the impact resistant layer.

Each of the window films manufactured in Examples 1 to 3 and Comparative Examples 1 to 4 was evaluated as to the following properties. Results are shown in Table 1.

### Property Evaluation

(1) Modulus of impact resistant layer (unit:MPa): Modulus was measured using a dynamic mechanical analyzer (DMA) (Q800 model, TA instruments Inc.). For example, storage modulus of the impact resistant layer was measured using dynamic mechanical analysis in tensile mode under conditions of a frequency of 1 Hz and a heating rate of 3° C./min from −40° C. to 70° C. after clamping both ends of a sample with a space of about 7 mm therebetween. The storage modulus was measured twice to ensure reliability of the results. Here, a 20 μm thick specimen of the impact resistant layer was used.
(2) Impact resistance (unit: cm, measured by pen drop test): An adhesive layer was formed on a lower surface of each of the window films manufactured in Examples 1 to 3 and Comparative Examples 1 to 4 (that is, a surface of the functional coating layer), followed by stacking a polyethylene terephthalate (PET) film (thickness: 125 μm) on the other surface of the window film, thereby preparing a specimen. A BIC ballpoint pen was freely dropped onto the specimen from varying heights above the hard coating layer of the specimen to determine a minimum height from which dropping the ballpoint pen resulted in cracking of the PET film (thickness: 125 μm). Observation of cracking was conducted using an optical microscope. A greater minimum height indicates better pen drop impact resistance.
(3) Light transmittance and haze (unit: %): Haze and light transmittance of each of the window films manufactured in Examples 1 to 3 and Comparative Examples 1 to 4 were measured using a haze meter (NDH2000, Nippon Denshoku Industries Co., Ltd.) and a spectrophotometer (CM-3600A, Konica Minolta Inc.), respectively.
(4) Rainbow mura: An adhesive and each of the window films manufactured in Examples 1 to 3 and Comparative Examples 1 to 4 were sequentially attached to an upper surface of a black sheet (with the hardcoating layer of the window film facing upwards), followed by evaluation of interference mura and rainbow mura with the naked eye at an angle of 45° under a three-wavelength light source. Rainbow mura of the window film was evaluated according to the following criteria:
⊚: Rainbow mura was not present at all.
∘: Rainbow mura was slightly present, but was not visible to the naked eye.
Δ: Rainbow mura was slightly present, but was not readily visible to the naked eye.
x: Rainbow mura was readily visible to the naked eye.
xx: Rainbow mura was very readily visible to the naked eye.

⊚ to Δ indicate that a corresponding window film can be effectively included in a display apparatus, and x and xx indicate that a corresponding window film cannot be included in a display apparatus.
(5) Flexural reliability (unit: number of cycles): Flexural reliability of each of the window films manufactured in Examples 1 to 3 and Comparative Examples 1 to 4 under repeated bending to a radius of curvature of 1 mm was evaluated under high temperature and high humidity conditions (60° C. and 95% RH) and low temperature conditions (−40° C.). The window film was cut into a rectangle having a size of 2.5 cm×15 cm (width×length), thereby preparing a specimen. While repeating a cycle in which the specimen was bent to bring the hard coating layer into contact with a jig with a curvature radius of 1 mm and was then unbent back to an original state thereof, a minimum number of cycles at which cracking began to occur on the window film was determined. In evaluation of flexural reliability, when the minimum number of cycles is 100,000 or more, a corresponding window film can be considered to have good flexural reliability.

TABLE 1

| | | Example | | | Comparative Example | | | |
|---|---|---|---|---|---|---|---|---|
| | | 1 | 2 | 3 | 1 | 2 | 3 | 4 |
| Thickness of impact resistance | | 40 | 20 | 40 | 40 | 40 | 40 | 40 |
| layer (μm) | | | | | | | | |
| Presence or absence of buffer | | Present | Present | Present | Present | Present | Absent | Present* |
| layer | | | | | | | | |
| Modulus of | @−20° C. | 200 | 200 | 50 | 20 | 400 | 200 | 200 |
| impact | @25° C. | 70 | 70 | 10 | 1 | 200 | 70 | 70 |
| resistance | @60° C. | 40 | 40 | 7 | 2 | 100 | 5 | 40 |
| layer (MPa) | | | | | | | | |
| Impact resistance (cm) | | 9 | 6 | 9 | 7 | 7 | 8 | 8 |
| Light transmittance (%) | | 91 | 91 | 91 | 91 | 91 | 91 | 91 |
| Haze (%) | | 0.6 | 0.6 | 0.6 | 0.6 | 0.6 | 0.6 | 0.6 |
| Rainbow mura | | ⊚ | ◯ | ⊚ | ⊚ | ⊚ | X | Δ |
| Flexural | High | 200,000 | 200,000 | 200,000 | 50,000 | 200,000 | 200,000 | 200,000 |
| reliability | temperature | | | | | | | |
| (number of | and high | | | | | | | |
| cycles) | humidity | | | | | | | |
| | conditions | | | | | | | |
| | Low | 100,000 | 100,000 | 100,000 | 100,000 | 30,000 | 100,000 | 100,000 |
| | temperature | | | | | | | |
| | conditions | | | | | | | |

*The buffer layer was formed between the base layer and the hard coating layer.

As can be seen from Table 1, the window film according to the present disclosure was significantly effective at the reduction or elimination of rainbow mura while providing good flexural reliability under low temperature conditions and high temperature and high humidity conditions.

It should be understood that various modifications, changes, alterations, and equivalent embodiments can be made by those skilled in the art without departing from the spirit and scope of the disclosure.

What is claimed is:

1. A flexible window film comprising:
a base layer;
a hard coating layer on an upper surface of the base layer;
a functional coating layer on a lower surface of the base layer; and
a buffer layer between the base layer and the functional coating layer,
wherein the functional coating layer has a modulus of about 50 MPa to about 300 MPa at −20° C.

2. The flexible window as claimed in claim 1, wherein the functional coating layer has a modulus of about 5 MPa to about 200 MPa at 25° C.

3. The flexible window film as claimed in claim 1, wherein the functional coating layer has a modulus of about 1 MPa to about 150 MPa at 60° C.

4. The flexible window film as claimed in claim 1, wherein a ratio of the modulus of the functional coating layer at 60° C. to the modulus of the functional coating layer at −20° C. ranges from about 1:2 to about 1:10.

5. The flexible window film as claimed in claim 1, wherein the functional coating layer comprises an impact resistant coating layer.

6. The flexible window film as claimed in claim 1, wherein the functional coating layer comprises a cured product of a composition comprising an elastomer resin.

7. The flexible window film as claimed in claim 6, wherein the elastomer resin comprises at least one of a urethane resin or a urethane (meth)acrylic resin.

8. The flexible window film as claimed in claim 6, wherein the functional coating layer comprises a cured product of a composition comprising: about 100 parts by weight of a base resin comprising at least one of a urethane resin or a urethane (meth)acrylic resin; and about 0.5 parts by weight to about 1.5 parts by weight of a photoinitiator.

9. The flexible window film as claimed in claim 1, wherein the buffer layer comprises an intermixing layer of the base layer and the functional coating layer.

10. The flexible window film as claimed in claim 1, wherein the content of at least one of a urethane resin or a urethane (meth)acrylic resin in the buffer layer gradually decreases from an interface between the buffer layer and the functional coating layer to an interface between the buffer layer and the base layer.

11. The flexible window film as claimed in claim 1, wherein the base layer has a modulus of about 3 GPa to about 10 GPa at 25° C.

12. The flexible window film as claimed in claim 1, wherein the base layer comprises a soluble polyimide resin film.

13. The flexible window film as claimed in claim 12, wherein the soluble polyimide resin film comprises a polyimide resin soluble in a solvent comprising at least one of methyl ethyl ketone, methyl isobutyl ketone, propylene glycol monomethyl ether, N,N-dimethylacetamide, or methyl pyrrolidone.

14. The flexible window film as claimed in claim 1, wherein a modulus ratio of a modulus of the functional coating layer at 25° C. to a modulus of the base layer at 25° C. ranges from about 1:50 to about 1:2,000.

15. The flexible window film as claimed in claim 1, wherein the hard coating layer comprises a (meth)acrylic coating layer.

16. The flexible window film as claimed in claim 1, further comprising;
an anti-fingerprint layer on an upper surface of the hard coating layer.

17. A display apparatus comprising the flexible window film as claimed in claim 1.
